(19) United States
(12) Patent Application Publication
(10) Pub. No.: US 2011/0186107 A1
(43) Pub. Date: Aug. 4, 2011

(54) SYSTEM AND MODULE FOR SOLAR MODULE WITH INTEGRATED GLASS CONCENTRATOR

(75) Inventors: Kevin R. GIBSON, Redwood City, CA (US); Abhay Maheshwari, Monte Sereno, CA (US)

(73) Assignee: Solaria Corporation, Fremont, CA (US)

(21) Appl. No.: 13/019,256

(22) Filed: Feb. 1, 2011

Related U.S. Application Data
(60) Provisional application No. 61/300,434, filed on Feb. 1, 2010.

(51) Int. Cl. H01L 31/05; H01L 31/052; H01L 31/18

(52) U.S. Cl. 136/246; 438/98; 257/E31.124

(57) ABSTRACT

A solar module includes a photovoltaic region having an elongated shape. At least one bus bar pad overlies portions of the photovoltaic region. The solar module includes an electrically conductive region configured along a periphery region of the photovoltaic region to expose an interior surface region of the photovoltaic strip. A finger structure configured to conduct electrical current generated in the photovoltaic regions overlies the electrically conductive region.

### CROSS-REFERENCES TO RELATED APPLICATIONS

This application claims priority to U.S. Provisional Patent Application No. 61/300434 filed Feb. 1, 2010, which has been incorporated by reference for all purposes.

### BACKGROUND OF THE INVENTION

The present invention relates generally to solar energy techniques. In particular, the present invention provides a method and a structure for a resulting solar module. Merely by way of example, the invention has been applied to solar panels, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable. Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable.

### BRIEF SUMMARY OF THE INVENTION

The present invention relates generally to solar energy techniques. In particular, the present invention provides a method and a structure for a resulting solar module. Merely by way of example, the invention has been applied to solar panels, but it would be recognized that the invention has a much broader range of applicability.

In a specific embodiment, a solar module includes at least a photovoltaic region, which is preferably spatially disposed in an array of photovoltaic regions. In a specific embodiment, each of the the photovoltaic region is provided in a strip configuration and elongated in shape. The photovoltaic region includes a width and a length. The solar module includes one or more bus bar pads overlying portions of each of the the photovoltaic regions. In a specific embodiment, each of the photovoltaic regions includes an electrically conductive region configured along a periphery region of each of the photovoltaic region to expose an interior surface region of the photovoltaic strip. The solar module includes a finger structure overlying the electrically conductive region. The finger structure is configured to conduct electrical current generated in each of the photovoltaic regions.

In an alternate embodiment, a method of manufacturing a solar module is provided. The method includes providing a substrate member, which can be a backsheet member in a specific embodiment. In a specific embodiment, a first finger element and a second finger element is provided. The first finger element and the second finger element are made of conductor material. The conductor material can be silver, copper, aluminum, an alloy or a composite material depending on the embodiment. The method includes providing a photovoltaic strip. The photovoltaic strip includes an electrically conductive region configured along a periphery region of the photovoltaic strip in a specific embodiment. In a specific embodiment, the periphery region includes a first edge region and a second edge region along a length of the photovoltaic strip. The method couples the first finger element to the first edge region of the photovoltaic strip and the second finger element to the second edge region of the photovoltaic strip exposing an inner surface region of the photovoltaic strip.

Many benefits can be achieved by ways of the present invention. For example, the present solar module provides a simplified structure for manufacturing process. The solar module according to the present invention eliminates the use of certain materials (e.g., acrylic) and reduces the amount of glass material for the concentrator structure. In a preferred embodiment, the present method and apparatus configures the plurality of photovoltaic strips to allow for a higher fill factor for the solar module and a higher conversion efficiency. The present solar module may be fabricated using a standard cell manufacturing process with few process steps resulting in lower cost and improved product reliability. The improved product reliability is at least due to less mismatch in thermal expansion coefficients of the materials.

### BRIEF DESCRIPTION OF THE DRAWINGS

FIG. 1 is a simplified diagram illustrating part of a conventional photovoltaic module.

FIGS. 2-4 are simplified diagram illustrating a photovoltaic module according to an embodiment of the present invention.

### DETAILED DESCRIPTION OF THE INVENTION

The present invention relates generally to solar energy techniques. In particular, the present invention provides a method and a structure for a resulting solar module. Merely by way of example, the invention has been applied to solar panels, but it would be recognized that the invention has a much broader range of applicability.

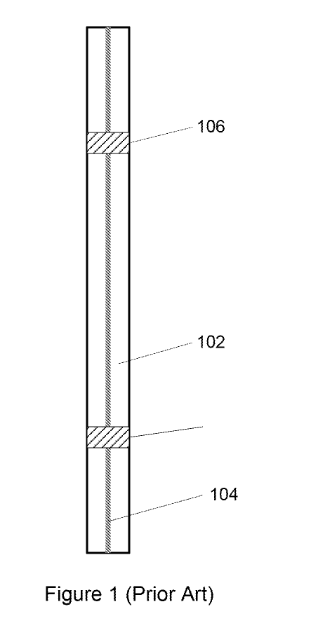

FIG. 1 is a simplified diagram illustrating a conventional solar module. As shown, the conventional module includes a photovoltaic region 102. The photovoltaic region is usually a semiconductor material such as single crystal silicon, polycrystalline silicon, thin file material such as CIGS, amorphous silicon, and others. As shown, the conventional solar module includes a conductor element 104 commonly known as finger, disposed on about a center region of the photovoltaic region. The solar module also includes bus bar pads 106 to allow the electric energy generated within the photovoltaic strip to be collected using a bus bar coupled to the bus bar pad. Depending on the incident sunlight, conductor element 104 may block the incident sunlight and the conversion efficiency is reduced.

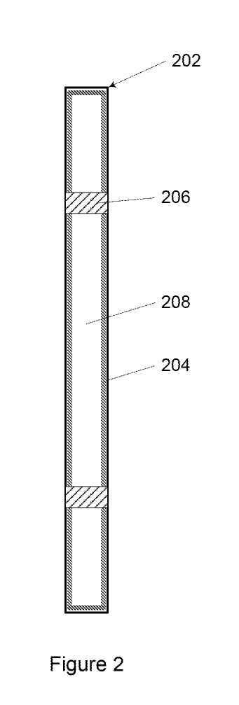

FIGS. 2-4 are simplified diagram illustrating a photovoltaic module according to an embodiment of the present invention. These diagrams are merely examples and should not unduly limit the claims herein. One skilled in the art would recognize other variations, modifications, and alternatives.

As shown in FIG. 2, the photovoltaic module includes a photovoltaic region 202. The photovoltaic region is provided as a photovoltaic strip characterized by a length and a width in a specific embodiment. The photovoltaic strip is formed using a singulation process in a specific embodiment. The photovoltaic strip can have a width ranging from about 1 mm to about 10 mm in a specific embodiment, but can be others depending on the application. The photovoltaic strip is spatially disposed in a 1×N photovoltaic strip array in a specific embodiment. As shown the photovoltaic region has a conductive region 204 configured on a peripheral region of the photovoltaic strip. As illustrated in FIG. 2, the photovoltaic module includes a first pair of conductor elements 210 or fingers operably coupled to each of the peripheral region along a length of the photovoltaic strip and an inner surface region 208 remain exposed in a specific embodiment. Many benefits can be realized by such a configuration. For example, by using a pair of fingers, a contact resistance between the finger and the photovoltaic strip can be better controlled due to reduced stress, and others. Additionally, the present finger configuration provides for an uniform cut for the singulation process and less likely for breakage of the fingers during processing. The photovoltaic strip may include a second conductor element or a second pair of conductor elements configured on each of the edge region along each of the width of the photovoltaic strip for alternate electrical conductor path in a specific embodiment.

Many advantages are achieved by ways of the present invention. For example, having the conductor elements along the periphery region of a photovoltaic strip improves overall performance as shadowing by the conductor elements is minimized or eliminated. Additionally, the solar module would have an improved winter month performance when the sun has a greatest angle of incidence to the solar module. The finger arrangement also provides for a redundant electrical path should breakage of one of the conductor element occurs.

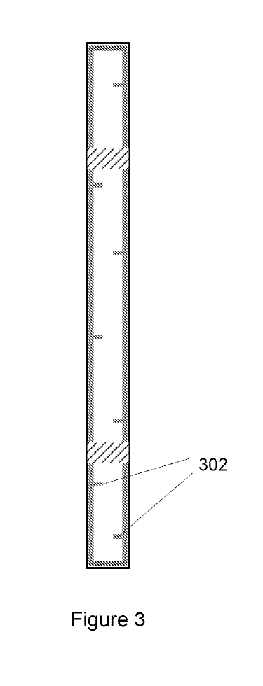

FIG. 3 is a simplified diagram illustrating an alternative arrangement of the conductor element according to an embodiment of the present invention. As shown, the conductor element further includes one or more finger stubs 302 extending from the fingers towards the center of the photovoltaic strip. The one or more finger stubs is preferred for a photovoltaic strip that is too wide for only edge fingers and to collect more electric energy from the photovoltaic region in a specific embodiment. In certain embodiments, each of the one or more finger stubs has a length about half the width of the photovoltaic region. Other configurations may also be used depending on the embodiment.

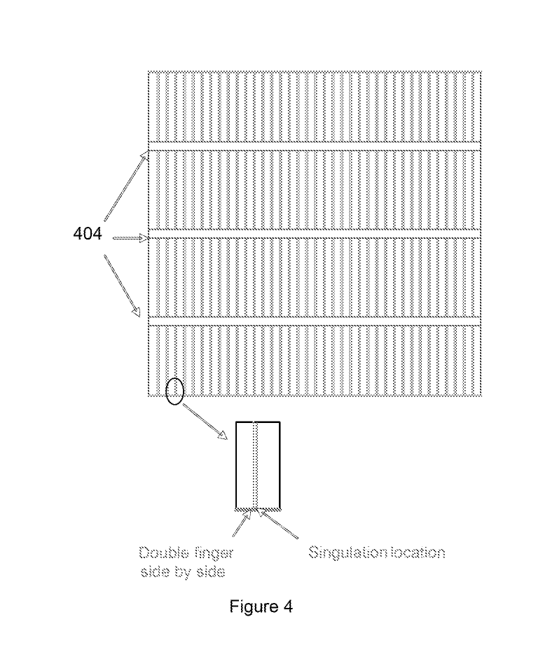

FIG. 4 is a simplified diagram illustrating a grid pattern for a solar module according to an embodiment of the present invention. As shown, the solar module includes a plurality of photovoltaic strips 402. Each of the photovoltaic strips is formed using a singulation process in a specific embodiment. As shown, each of the photovoltaic strips is arranged parallel to each other along the length. In a specific embodiment, each of the photovoltaic strips is singulated along the length, as shown. As described, each of the photovoltaic strips includes a pair of fingers or conductor elements configured in a peripheral region of each of the photovoltaic strip. The conductor elements collect electric current generated from each of the photovoltaic strips. The photovoltaic module also includes one or more bus bars 404 connecting each of the photovoltaic strips allowing electric energy to be collected from each of the photovoltaic regions.

In a specific embodiment, the solar module further includes an concentrator system optically coupled to each of the photovoltaic strips to provide for a large area solar module. The concentrator system is fabricated using a glass material in a specific embodiment. In a preferred embodiment, the concentrator system also provides a front cover for the solar module. Further details of the glass concentrator system is described in Provisional Application 61/154,357, filed on Feb. 20, 2009, commonly assigned, and incorporated by reference for all purpose herein. Of course there can be other variations, modifications, and alternatives.

In a specific embodiment, a method for forming a solar module is provided. The method includes providing a substrate member or a backsheet member. The method provides a photovoltaic strip having a length and a width spatially disposed on a surface region of the backsheet member. In a specific embodiment, the photovoltaic strip includes an electrically conductive region configured along a periphery region of the photovoltaic strip. The periphery region includes a first edge region and a second edge region along a length of the photovoltaic strip in a specific embodiment. In a specific embodiment, the method includes coupling a first conductor element and a second conductor element to the electrically conductor region in the periphery region. An inner surface region of the photovoltaic strip remains exposed. In a preferred embodiment, the electrically conductive region includes a first edge region and a second edge region along the length of the photovoltaic strip. Of course there can be other, variations, modifications, and alternatives.

In a specific embodiment, the photovoltaic strip together with the conductor elements provides for a large area solar module. In a specific embodiment, the large area solar module includes N photovoltaic strips, each of the N photovoltaic strips is coupled to a pair of conductor elements. In certain embodiments, the N photovoltaic strips can further coupled to a front cover member. The front cover member can be a large area concentrator member, allowing for optical magnification in a specific embodiment.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A solar module, comprising;
a photovoltaic region, the photovoltaic region being elongated in shape, the photovoltaic region having a width and a length;
at least one bus bar pad overlying portions of the photovoltaic region;
an electrically conductive region configured along a periphery region of the photovoltaic region to expose an interior surface region of the photovoltaic strip; and
a finger structure overlying the electrically conductive region, the finger structure being configured to conduct electrical current generated in the photovoltaic regions.

2. The solar module of claim 1 wherein the photovoltaic region comprises single crystal silicon material.

3. The solar module of claim 1 wherein the photovoltaic region comprises polycrystalline silicon material.

4. The solar module of claim 1 wherein the photovoltaic region is provided in an array having N photovoltaic regions.

5. The solar module of claim 1 wherein the finger structure comprises two finger elements spatially disposed along each of the lengths of the photovoltaic region.

6. The solar module of claim 1 wherein the finger structure comprises a conductor material such as silver or copper or aluminum.

7. The solar module of claim 1 wherein the finger structure further comprises one or more end conductor elements for alternate electrical conduction path spatially disposed along each of the width of the photovoltaic region.

8. The solar module of claim 1 wherein the photovoltaic region is rectangular in shape.

9. The solar module of claim 1 wherein the finger structure further comprises a plurality of stubs oriented towards the center of the photovoltaic region, each of the stub has a length of about half of the width of the photovoltaic region.

10. The solar module of claim 1 wherein the finger structure provides for a maximum fill factor for the photovoltaic region.

11. The solar module of claim 1 wherein the bus bar pads provide for a bus bar and electrical connection between the photovoltaic regions in the array.

12. The solar module of claim 1 wherein the array of photovoltaic regions is aligned to a glass optical concentrator system.

13. A method of manufacturing a solar module, comprising:
providing a substrate member;
providing a first finger element and a second finger element;
providing a photovoltaic strip comprising an electrically conductive region configured along a periphery region of the photovoltaic strip; the periphery region comprising a first edge region and a second edge region along a length of the photovoltaic strip and
coupling the first finger element to the first edge region of the photovoltaic strip and the second finger element to the second edge region of the photovoltaic strip exposing a inner surface region of the photovoltaic strip.
